(19) United States
(12) Patent Application Publication
(10) Pub. No.: US 2023/0197420 A1
(43) Pub. Date: Jun. 22, 2023

(54) MONOBLOC PEDESTAL FOR EFFICIENT HEAT TRANSFER

(71) Applicant: LAM RESEARCH CORPORATION, Fremont, CA (US)

(72) Inventor: Prahalad Narasinghdas AGARWAL, Bangalore (IN)

(21) Appl. No.: 17/928,747

(22) PCT Filed: Jun. 2, 2021
(86) PCT No.: PCT/US2021/035329

§ 371 Date: Nov. 30, 2022

Related U.S. Application Data
(60) Provisional application No. 63/033,979, filed on Jun. 3, 2020.

(51) Int. Cl. H01J 37/32

(52) U.S. Cl. CPC H01J 37/32724; H01J 2237/3321

(57) ABSTRACT

A substrate support for a substrate processing system includes a monobloc pedestal plate with a first surface configured to support a substrate and a second surface configured to interface with a pedestal stem. A groove is formed in the second surface of the monobloc pedestal plate. The groove has a serpentine shape and a depth of the groove extends upward from the second surface of the monobloc pedestal plate. A heater coil is arranged within the groove. A gap is defined between the heater coil and the second surface of the monobloc pedestal plate and a gap material is arranged within the gap to seal the heater coil within the groove.

### CROSS-REFERENCE TO RELATED APPLICATIONS

This application claims the benefit of U.S. Provisional Application No. 63/033,979, filed on Jun. 3, 2020. The entire disclosure of the application referenced above is incorporated herein by reference.

### FIELD

The present disclosure relates to substrate supports for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are used to perform treatments such as deposition and etching of film on substrates such as semiconductor wafers. For example, deposition may be performed to deposit conductive film, dielectric film, or other types of film using chemical vapor deposition (CVD), plasma enhanced CVD (PECVD), atomic layer deposition (ALD), plasma enhance ALD (PEALD), and/or other deposition processes. During deposition, the substrate is arranged on a substrate support (e.g., a pedestal) and one or more precursor gases may be supplied to a processing chamber during one or more process steps. In a PECVD or PEALD process, plasma is used to activate chemical reactions within the processing chamber during deposition.

### SUMMARY

A substrate support for a substrate processing system includes a monobloc pedestal plate with a first surface configured to support a substrate and a second surface configured to interface with a pedestal stem. A groove is formed in the second surface of the monobloc pedestal plate. The groove has a serpentine shape and a depth of the groove extends upward from the second surface of the monobloc pedestal plate. A heater coil is arranged within the groove. A gap is defined between the heater coil and the second surface of the monobloc pedestal plate and a gap material is arranged within the gap to seal the heater coil within the groove.

In other features, the monobloc pedestal plate is comprised of a material that includes aluminum. The heater coil comprises aluminum. The gap material comprises aluminum. The monobloc pedestal plate and the gap material are comprised of a same material. A thermal conductivity of the gap material is within 5% of a thermal conductivity of the monobloc pedestal plate. The depth of the groove is 40-60% of a thickness of the monobloc pedestal plate.

In other features, the substrate support further includes a recess formed in the second surface of the monobloc pedestal plate. The pedestal stem is arranged within the recess. A shape of the groove is at least one of annular, helical, and oscillating. The groove is at least one of machined, milled, and etched into the second surface of the monobloc pedestal plate. The heater coil has a coating that is electrically insulative and thermally conductive. The coating is a thermally conductive epoxy. The heater coil is friction stir welded within the groove.

A method for assembling a substrate support for a substrate processing system includes providing a monobloc pedestal plate comprising a first surface configured to support a substrate and a second surface configured to interface with a pedestal stem and forming a groove in the second surface of the monobloc pedestal plate. The groove has a serpentine shape and a depth of the groove extends upward from the second surface of the monobloc pedestal plate. The method further includes arranging a heater coil within the groove. The gap is defined between the heater coil and the second surface of the monobloc pedestal plate and filled with a gap material to seal the heater coil within the groove.

In other features, the monobloc pedestal plate is comprised of a material that includes aluminum. The heater coil comprises aluminum. The gap material comprises aluminum. A thermal conductivity of the gap material is within 5% of a thermal conductivity of the monobloc pedestal plate. The method further includes forming a recess in the second surface of the monobloc pedestal plate and arranging the pedestal stem within the recess. The method further includes at least one of machining, milling, and etching the groove into the second surface of the monobloc pedestal plate. The method further includes friction stir welding the heater coil within the groove.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system according to the present disclosure;

FIGS. 2A, 2B, 2C, and 2D show an process for manufacturing an example monobloc pedestal according to the present disclosure;

FIG. 3A is a bottom view of a monobloc pedestal according to the present disclosure;

FIG. 3B is an isometric view of a monobloc pedestal and stem according to the present disclosure;

FIG. 3C is a bottom view of a monobloc pedestal and stem according to the present disclosure; and

FIG. 4 illustrate steps of an example method of manufacturing a monobloc pedestal according to the present disclosure.

In the drawings, reference numbers may be reused to identify similar and/or identical elements.

### DETAILED DESCRIPTION

Typically, substrate supports such as temperature-controlled pedestals include multiple layers and materials. For example, a substrate support may include multiple metal layers and/or ceramic layers. One or more heater layers or coils may be embedded within a metal or ceramic layer, arranged between adjacent metal or ceramic layers, etc. In some examples, layers of the substrate support are welded or laminated together and the heater coils are brazed (e.g., vacuum brazed) or welded to one of the layers. However, welded interfaces between layers of the substrate support and/or between the heater coils and the layers of the substrate support may deteriorate over time and cause reduced thermal uniformity and inefficient heat transfer. Further, assembling the substrate support using multiple layers increases manufacturing complexity, cost, and lead time.

The substrate support according to the present disclosure implements a single metallic plate (e.g., a monobloc substrate support) comprised of a single material with an embedded heater coil. For example, the heater coils are friction stir welded into a channel formed within the plate. The monobloc substrate support has a uniform grain structure resulting in improved thermal and mechanical performance, simpler manufacturing, and reduced cost relative to substrate supports comprising multiple welded layers.

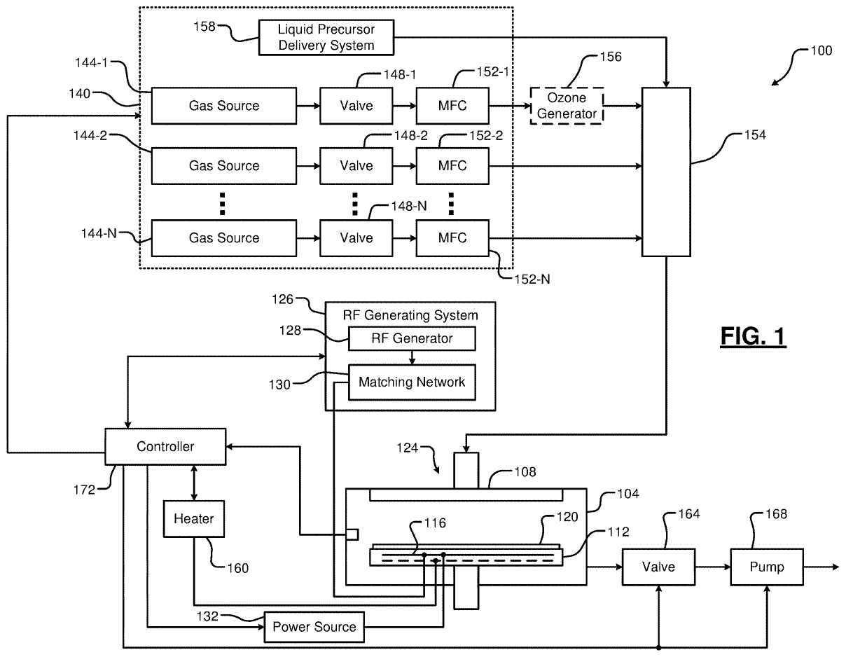

Referring now to FIG. 1, an example of a substrate processing system 100 according to the principles of the present disclosure is shown. While the foregoing example relates to PECVD systems, other plasma-based substrate processing chambers may be used. The substrate processing system 100 includes a processing chamber 104 that encloses other components of the substrate processing system 100. The substrate processing system 100 includes a first (e.g., upper) electrode 108 and a substrate support such as a pedestal 112 including a second (e.g., lower) electrode 116. A substrate 120 is arranged on the pedestal 112 between the upper electrode 108 and the lower electrode 116.

For example only, the upper electrode 108 may include a showerhead 124 that introduces and distributes process gases. Alternately, the upper electrode 108 may include a conducting plate and the process gases may be introduced in another manner. In some examples, the lower electrode 116 may correspond to a conductive electrode embedded within a non-conductive pedestal. Alternately, the pedestal 112 may include an electrostatic chuck that includes a conductive plate that acts as the lower electrode 116.

A radio frequency (RF) generating system 126 generates and outputs an RF voltage to the upper electrode 108 and/or the lower electrode 116 when plasma is used. In some examples, one of the upper electrode 108 and the lower electrode 116 may be DC grounded, AC grounded, or at a floating potential. For example only, the RF generating system 126 may include one or more RF voltage generators 128 (e.g., a capacitively-coupled plasma RF power generator, a bias RF power generator, and/or other RF power generator) such as an RF generator 128 that generate RF voltages, which are fed by one or more matching and distribution networks 130 to the lower electrode 116 and/or the upper electrode 108. For example, as shown, the RF generator 128 provides an RF and/or bias voltage to the lower electrode 116. The lower electrode 116 may receive power alternatively or additionally from other power sources, such as a power source 132. In other example, an RF voltage may be supplied to the upper electrode 108 or the upper electrode 108 may be connected to a ground reference.

An example gas delivery system 140 includes one or more gas sources 144-1, 144-2, . . . , and 144-N (collectively gas sources 144), where N is an integer greater than zero. The gas sources 144 supply one or more gases (e.g., precursors, inert gases, etc.) and mixtures thereof. Vaporized precursor may also be used. At least one of the gas sources 144 may contain gases used in the pre-treatment process of the present disclosure (e.g., NH₃, N₂, etc.). The gas sources 144 are connected by valves 148-1, 148-2, . . . , and 148-N (collectively valves 148) and mass flow controllers 152-1, 152-2, . . . , and 152-N (collectively mass flow controllers 152) to a manifold 154. An output of the manifold 154 is fed to the processing chamber 104. For example only, the output of the manifold 154 is fed to the showerhead 124. In some examples, an optional ozone generator 156 may be provided between the mass flow controllers 152 and the manifold 154. In some examples, the substrate processing system 100 may include a liquid precursor delivery system 158. The liquid precursor delivery system 158 may be incorporated within the gas delivery system 140 as shown or may be external to the gas delivery system 140. The liquid precursor delivery system 158 is configured to provide precursors that are liquid and/or solid at room temperature via a bubbler, direct liquid injection, vapor draw, etc.

A heater 160 may be connected to a heater coil 162 arranged in the pedestal 112 to heat the pedestal 112. The heater 160 may be used to control a temperature of the pedestal 112 and the substrate 120. The pedestal 112 according to the present disclosure comprises a monobloc plate with the heater coil 162 embedded therein as described below in more detail.

A valve 164 and pump 168 may be used to evacuate reactants from the processing chamber 104. A controller 172 may be used to control various components of the substrate processing system 100. For example only, the controller 172 may be used to control flow of process, carrier and precursor gases, striking and extinguishing plasma, removal of reactants, monitoring of chamber parameters, etc.

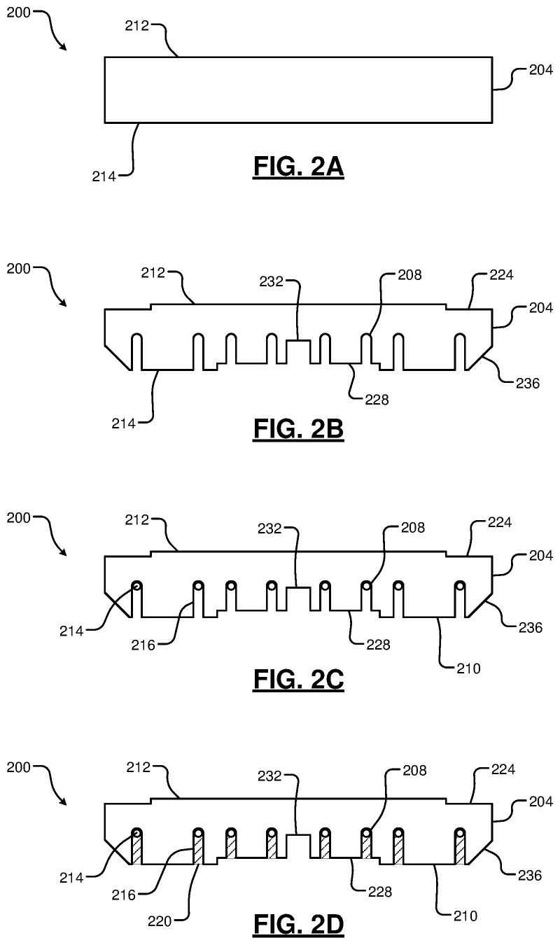

FIGS. 2A-2D show a process for manufacturing an example monobloc pedestal 200 according to the present disclosure. As used herein, “monobloc” refers to a pedestal that is formed from a single block or casting. A shown in FIG. 2A, the pedestal 200 is formed from a single block or plate 204 (i.e., a monobloc pedestal plate). For example, the plate 204 comprises a metallic material such as aluminum cast in a generally rectangular shape. The material of the plate 204 has a uniform grain structure.

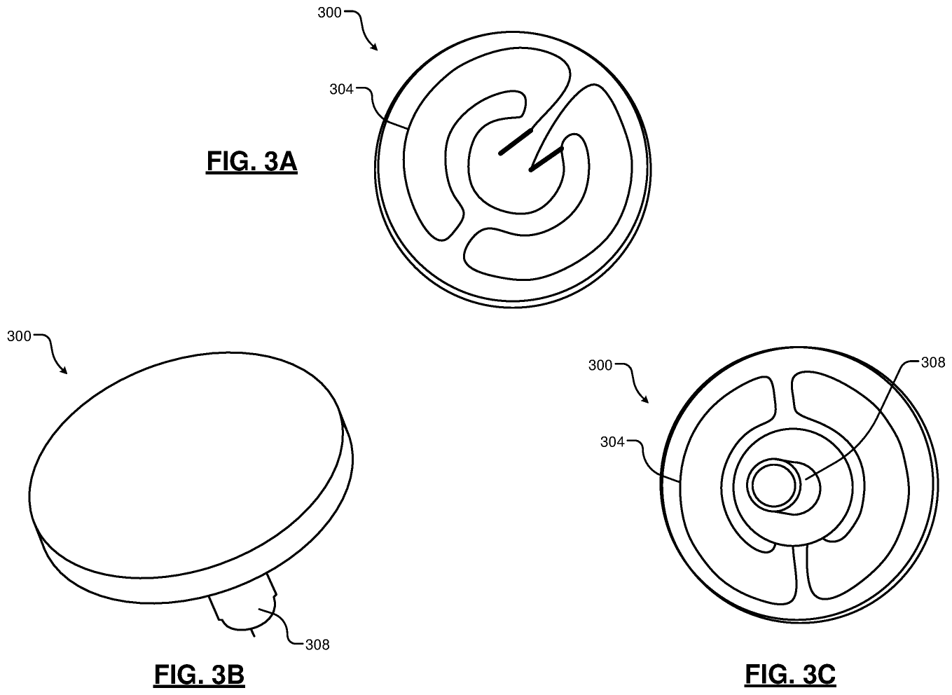

As shown in FIG. 2B, features corresponding to a final desired shape of the pedestal 200 are formed in the plate 204. For example, a channel or groove 208 is formed in a second (e.g., lower) surface 210 of the plate 204. The groove 208 is generally serpentine and may have a shape (i.e., in a plan view) that is circular or annular, helical, oscillating, etc. as shown in more detail below in FIGS. 3A-3C. The plate 204 may be machined, milled, etched, laser-ablated, etc. to form the groove 208. The groove 208 (i.e., a vertical depth of the groove) extends upward from the lower surface 210 of the plate 204. For example, a depth of the groove 208 may correspond to 40-60% of a thickness of the plate 204. As shown, the depth of the groove 208 is approximately 50% (e.g., +/−2%) of the thickness of the plate 204.

A first (e.g., upper) surface 212 of the plate 204 corresponds to an upper support surface of the pedestal 200. In other words, the plate 204 is configured to support a substrate (e.g., the substrate 120) directly on the upper surface 212 without any additional layers arranged between the substrate and the upper surface 212.

As shown in FIG. 2C, a heater coil 214 is arranged within the groove 208 (i.e., at a top end of the groove 208). Since the groove 208 extends from the lower surface 210 of the plate 204 into an interior region of the plate 204, the heater coil 214 can be directly embedded within the plate 204 via the groove 208 extending from the lower surface 210. For example, the heater coil 214 is friction stir welded into the groove 208. Friction stir welding refers to a solid-state welding process in which two or more components (e.g., the plate 204 and the heater coil 214) are welded together, without melting either of the components, by generating friction between the components. In other examples, the heater coil 214 is attached within the groove 208 using another suitable welding or joining method, a thermal adhesive (e.g., a thermally conductive epoxy), etc. The heater coil 214 may be comprised of a same material as the plate 204 or a different material. For example, the heater coil 214 may be comprised of aluminum and has an electrically insulative, thermally conductive coating. For example, the heater coil 214 may be coated in a thermally conductive epoxy. Although shown having a round cross-section, in some examples the heater coil 214 may have a flat rectangular shape (e.g., the heater coil 214 may be formed as an electrical trace).

In other examples, the depth of the groove 208 may be extended or shortened to correspondingly decrease or increase a distance of the heater coil 214 from the upper surface 212 of the plate 204. In this manner, distribution of heat from the heater coil 214 to the upper surface 212 can be customized for respective pedestals and/or processes.

The heater coil 214 is configured to function as a resistive heater. In other words, power is provided to the heater coil 214 (e.g., via the heater 160) to flow current though the heater coil 214. The current heats the heater coil 214, which distributes heat throughout the plate 204. The monobloc plate 204 comprising a single material and uniform grain structure facilitates uniform distribution of heat from the heater coil 214 and into the plate 204. For example, since the plate 204 is not comprised of multiple layers, distribution of heat from the heater coil 214 is not impeded by interfaces between different layers, through adhesive or other intermediate materials arranged between different layers, etc.

A gap 216 below the heater coil 214 (i.e., between the heater coil 214 and the lower surface 210) may be filled with a gap material 220 as shown in FIG. 2D. The gap material 220 seals the heater coil 214 within the groove 208. The gap material 220 may be comprised of a same material as the plate 204 or a different material. For example, the gap material 220 may be comprised of aluminum. If the gap material 220 is a material different from the plate 204, the gap material 220 may be selected to have the same or similar thermal conductivity and/or electrical conductivity characteristics as the plate 204. For example, the thermal conductivity of the gap material 220 is within 5% of the thermal conductivity of the plate 204.

As shown, the pedestal 200 may include other features that are formed using a same process used to form the groove 208. In some examples, all of the features are formed in same step (e.g., a same machining or milling step). For example, an annular ledge or step 224 may be formed in the upper surface 212 of the pedestal 200. In some examples, the step 224 may be configured to support an edge ring. A recess 228 and central opening 232 are formed in the bottom surface 210. For example, the recess 228 is configured to interface with a pedestal stem (e.g., as shown in FIGS. 3B and 3C) and the central opening 232 is configured to receive wiring connections for powering the heater coil 214, providing RF power to the pedestal 200, etc. A lower annular edge 236 of the pedestal may be chamfered or beveled.

Referring now to FIGS. 3A, 3B, and 3C, an example monobloc pedestal 300 according to the present disclosure is shown. FIGS. 3A is a bottom view of the monobloc pedestal 300. A groove 304 is formed in an underside of the pedestal 300. One example shape or pattern of the groove 304. In other examples, the groove 304 may have different shapes. For example, the groove 304 may have a circular, helical, or oscillating (e.g., sinusoidal or zig-zagging) pattern. Although only one of the grooves 304 is shown, in other examples the pedestal 300 may include two more of the grooves 304, each accommodating a different heater coil. FIG. 3B is an isometric view of the pedestal 300 including a stem 308. FIG. 3C is a bottom view of the pedestal 300 including the stem 308.

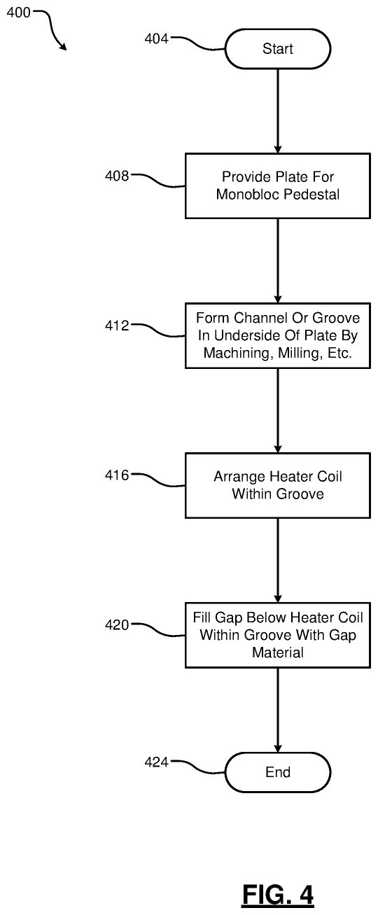

Referring now to FIG. 4, an example method 400 of manufacturing a monobloc pedestal (e.g., the pedestal 200) according to the present disclosure begins at 404. At 408, a single block or plate is provided. At 412, a channel or groove is formed in an underside of the plate. For example, the groove is machined, milled, etched, laser-ablated, etc. At 416, a heater coil is arranged within the groove. At 420, a gap below the heater coil within the groove is filed with a gap material. The method 400 ends at 424.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate support for a substrate processing system, the substrate support comprising:
a monobloc pedestal plate comprising a first surface configured to support a substrate and a second surface configured to interface with a pedestal stem;
a groove formed in the second surface of the monobloc pedestal plate, wherein the groove has a serpentine shape and a depth of the groove extends upward from the second surface of the monobloc pedestal plate; and
a heater coil arranged within the groove, wherein (i) a gap is defined between the heater coil and the second surface of the monobloc pedestal plate and (ii) a gap material is arranged within the gap to seal the heater coil within the groove.

2. The substrate support of claim 1, wherein the monobloc pedestal plate is comprised of a material that includes aluminum.

3. The substrate support of claim 1, wherein the heater coil comprises aluminum.

4. The substrate support of claim 1, wherein the gap material comprises aluminum.

5. The substrate support of claim 1, wherein the monobloc pedestal plate and the gap material are comprised of a same material.

6. The substrate support of claim 1, wherein a thermal conductivity of the gap material is within 5% of a thermal conductivity of the monobloc pedestal plate.

7. The substrate support of claim 1, wherein the depth of the groove is 40-60% of a thickness of the monobloc pedestal plate.

8. The substrate support of claim 1, further comprising a recess formed in the second surface of the monobloc pedestal plate, wherein the pedestal stem is arranged within the recess.

9. The substrate support of claim 1, wherein a shape of the groove is at least one of annular, helical, and oscillating.

10. The substrate support of claim 1, wherein the groove is at least one of machined, milled, and etched into the second surface of the monobloc pedestal plate.

11. The substrate support of claim 1, wherein the heater coil has a coating that is electrically insulative and thermally conductive.

12. The substrate support of claim 11, wherein the coating is a thermally conductive epoxy.

13. The substrate support of claim 1, wherein the heater coil is friction stir welded within the groove.

14. A method for assembling a substrate support for a substrate processing system, the method comprising:
providing a monobloc pedestal plate comprising a first surface configured to support a substrate and a second surface configured to interface with a pedestal stem;
forming a groove in the second surface of the monobloc pedestal plate, wherein the groove has a serpentine shape and a depth of the groove extends upward from the second surface of the monobloc pedestal plate;
arranging a heater coil within the groove, wherein a gap is defined between the heater coil and the second surface of the monobloc pedestal plate; and
filling the gap with a gap material to seal the heater coil within the groove.

15. The method of claim 14, wherein the monobloc pedestal plate is comprised of a material that includes aluminum.

16. The method of claim 14, wherein the heater coil comprises aluminum.

17. The method of claim 14, wherein the gap material comprises aluminum.

18. The method of claim 14, wherein a thermal conductivity of the gap material is within 5% of a thermal conductivity of the monobloc pedestal plate.

19. The method of claim 14, further comprising forming a recess in the second surface of the monobloc pedestal plate and arranging the pedestal stem within the recess.

20. The method of claim 14, further comprising at least one of machining, milling, and etching the groove into the second surface of the monobloc pedestal plate.
